(19) United States
(12) Patent Application Publication
(10) Pub. No.: US 2022/0085279 A1
(43) Pub. Date: Mar. 17, 2022

(54) MAGNETIC MEMORY DEVICE

(71) Applicant: Kioxia Corporation, Tokyo (JP)

(72) Inventors: Kazuya SAWADA, Seoul (KR); Young Min EEH, Seongnam-si Gyeonggi-do (KR); Tadaaki OIKAWA, Seoul (KR); Eiji KITAGAWA, Seoul (KR); Taiga ISODA, Seoul (KR)

(73) Assignee: Kioxia Corporation, Tokyo (JP)

(21) Appl. No.: 17/471,340

(22) Filed: Sep. 10, 2021

(30) Foreign Application Priority Data
Sep. 17, 2020 (JP) 2020-156153

(51) Int. Cl. H01L 43/02; H01L 43/10; H01L 27/22; H01L 43/12; G11C 11/16

(52) U.S. Cl. CPC H01L 43/02; H01L 43/10; G11C 11/161; H01L 27/228; H01L 43/12; H01L 27/224

(57) ABSTRACT

According to one embodiment, a magnetic memory device includes a magnetoresistance effect element. The magnetoresistance effect element includes a first ferromagnetic layer, a second ferromagnetic layer, a third ferromagnetic layer, a first non-magnetic layer between the first ferromagnetic layer and the second ferromagnetic layer, and a second non-magnetic layer between the second ferromagnetic layer and the third ferromagnetic layer. The second ferromagnetic layer is between the first ferromagnetic layer and the third ferromagnetic layer. The first non-magnetic layer contains an oxide containing magnesium (Mg). The third ferromagnetic layer contains silicon (Si) or germanium (Ge).

### CROSS-REFERENCE TO RELATED APPLICATIONS

This application is based upon and claims the benefit of priority from Japanese Patent Application No. 2020-156153, filed Sep. 17, 2020, the entire contents of which are incorporated herein by reference.

### FIELD

Embodiments described herein relate generally to a magnetic memory device.

### BACKGROUND

A magnetic memory device (magnetoresistive random access memory (MRAM)), which adopts a magnetoresistance effect element as a memory element, has been known.

### BRIEF DESCRIPTION OF THE DRAWINGS

FIG. 1 is a block diagram illustrating a configuration of a magnetic memory device according to an embodiment.

FIG. 2 is a circuit diagram illustrating a configuration of a memory cell array of the magnetic memory device according to the embodiment.

FIG. 3 is a cross-sectional view illustrating a configuration of the memory cell array of the magnetic memory device according to the embodiment.

FIG. 4 is a cross-sectional view illustrating a configuration of the memory cell array of the magnetic memory device according to the embodiment.

FIG. 5 is a cross-sectional view illustrating a configuration of a magnetoresistance effect element of the magnetic memory device according to the embodiment.

FIG. 6 is a schematic diagram illustrating a method of manufacturing the magnetoresistance effect element in the magnetic memory device according to the embodiment.

FIG. 7 is a diagram illustrating distribution of diffusion suppression elements in the magnetoresistance effect element of the magnetic memory device according to the embodiment before annealing process.

FIG. 8 is a schematic diagram illustrating a method of manufacturing the magnetoresistance effect element in the magnetic memory device according to the embodiment.

FIG. 9 is a diagram illustrating an advantageous effect of the embodiment.

FIG. 10 is a circuit diagram illustrating a configuration of a memory cell array of a magnetic memory device according to a modification.

FIG. 11 is a cross-sectional view illustrating a configuration of a memory cell of the magnetic memory device according to the modification.

### DETAILED DESCRIPTION

In general, according to one embodiment, a magnetic memory device includes a magnetoresistance effect element. The magnetoresistance effect element includes a first ferromagnetic layer, a second ferromagnetic layer, a third ferromagnetic layer, a first non-magnetic layer between the first ferromagnetic layer and the second ferromagnetic layer, and a second non-magnetic layer between the second ferromagnetic layer and the third ferromagnetic layer. The second ferromagnetic layer is between the first ferromagnetic layer and the third ferromagnetic layer. The first non-magnetic layer contains an oxide containing magnesium (Mg). The third ferromagnetic layer contains silicon (Si) or germanium (Ge).

Hereinafter, embodiments will be described with reference to the accompanying drawings. In the description below, constituent elements having the same function and configuration will be assigned a common reference numeral or symbol. When a plurality of constituent elements assigned a common reference numeral or symbol are distinguished from each other, suffixes are added after the common reference numeral or symbol to enable distinction. When a plurality of constituent elements are not particularly distinguished from each other, the constituent elements are assigned only a common reference numeral or symbol without suffixes. Suffixes are not limited to a subscript or a superscript, but include, for example, a lower-case alphabetical letter added at the end of a reference numeral or symbol, and an index indicating a disposition.

1 Embodiment

A magnetic memory device according to an embodiment will be described. Examples of the magnetic memory device according to the embodiment include a magnetic memory device of a perpendicular magnetic recording type which uses, as a variable resistance element, an element (MTJ element) that exhibits a magnetoresistance effect through a magnetic tunnel junction (MTJ). The MTJ element may be referred to as a “magnetoresistance effect element”. In the following embodiments, including the present embodiment, a case, where an MTJ element is adopted as a magnetoresistance effect element will be described. For the convenience of description, the representation “magnetoresistance effect element MTJ” will be used.

1.1 Configuration

First, a configuration of a magnetic memory device according to an embodiment will be described.

1.1.1 Magnetic Memory Device

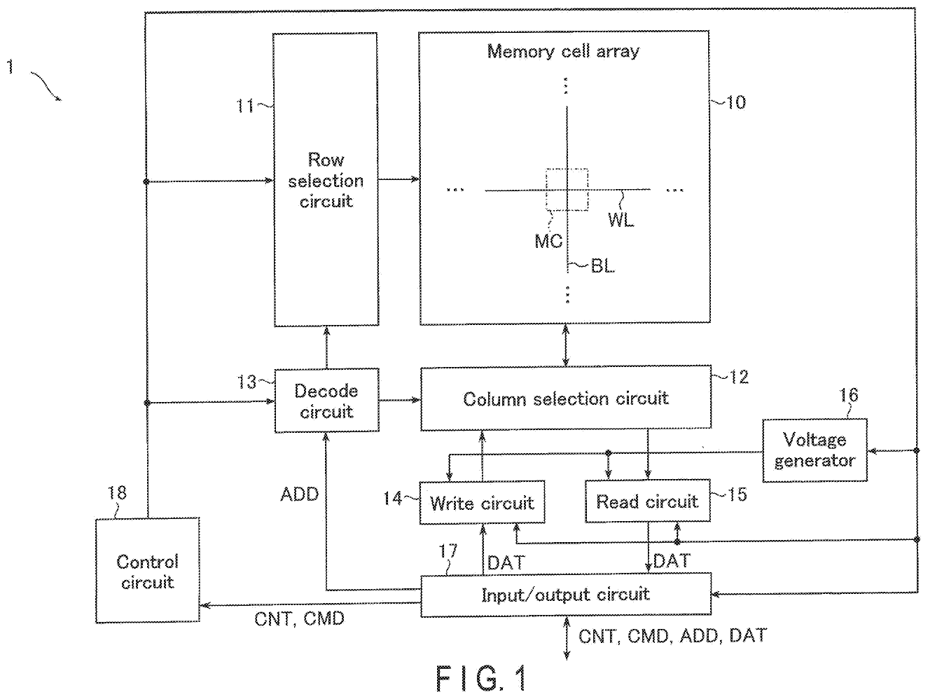

FIG. 1 is a block diagram showing a configuration of a magnetic memory device according to an embodiment. As shown in FIG. 1, a magnetic memory device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC each associated with a set including a row and a column. Specifically, memory cells MC in the same row are coupled to the same word line WL, and memory cells MC in the same column are coupled to the same bit line BL.

The row selection circuit 11 is coupled to the memory cell array 10 via word lines WL. The row selection circuit 11 is supplied with a decoding result (row address) of an address ADD from the decode circuit 13. The row selection circuit 11 sets a word line WL of a row corresponding to the decoding result of the address ADD to a selected state. Hereinafter, the word line WL set to the selected state will be referred to as a “selected word line WL”. The word lines WL other than the selected word line WL will be referred to as “non-selected word lines WL”.

The column selection circuit 12 is coupled to the memory cell array 10 via bit lines BL. The column selection circuit 12 is supplied with a decoding result (column address) of the address ADD from the decode circuit 13. The column selection circuit 12 sets a bit line BL of a column corresponding to the decoding result of the address ADD to a selected state. Hereinafter, the bit line BL set to the selected state will be referred to as a “selected bit line BL”. The bit lines BL other than the selected bit line BL will be referred to as “non-selected bit lines BL”.

The decode circuit 13 decodes an address ADD received from the input/output circuit 17. The decode circuit 13 supplies decoding results of the address ADD to the row selection circuit 11 and the column selection circuit 12. The address ADD includes addresses of a column and row to be selected.

The write circuit 14 writes data in memory cells MC. The write circuit 14 includes, for example, a write driver (not shown).

The read circuit 15 reads data from memory cells MC. The read circuit 15 includes, for example, a sense amplifier (not shown).

The voltage generator 16 generates voltages for various operations of the memory cell array 10, using a power supply voltage provided from the outside (not shown) of the magnetic memory device 1. For example, the voltage generator 16 generates various voltages necessary for a write operation, and outputs the generated voltages to the write circuit 14. Also, for example, the voltage generator 16 generates various voltages necessary for a read operation, and outputs the generated voltages to the read circuit 15.

The input/output circuit 17 transfers an address ADD received from the outside of the magnetic memory device 1, to the decode circuit 13. The input/output circuit 17 also transfers a command CMD received from the outside of the magnetic memory device 1, to the control circuit 18. The input/output circuit 17 transmits and receives various control signals CNT between the outside of the magnetic memory device 1 and the control circuit 18. The input/output circuit 17 transfers to the write circuit 14 data DAT received from the outside of the magnetic memory device 1, and outputs to the outside of the magnetic memory device 1 data DAT transferred from the read circuit 15.

The control circuit 18 controls the operations of the row selection circuit 11, column selection circuit 12, decode circuit 13, write circuit 14, read circuit 15, voltage generator 16, and input/output circuit 17 in the magnetic memory device 1, based on the control signals CNT and command CMD.

1.1.2 Memory Cell Array

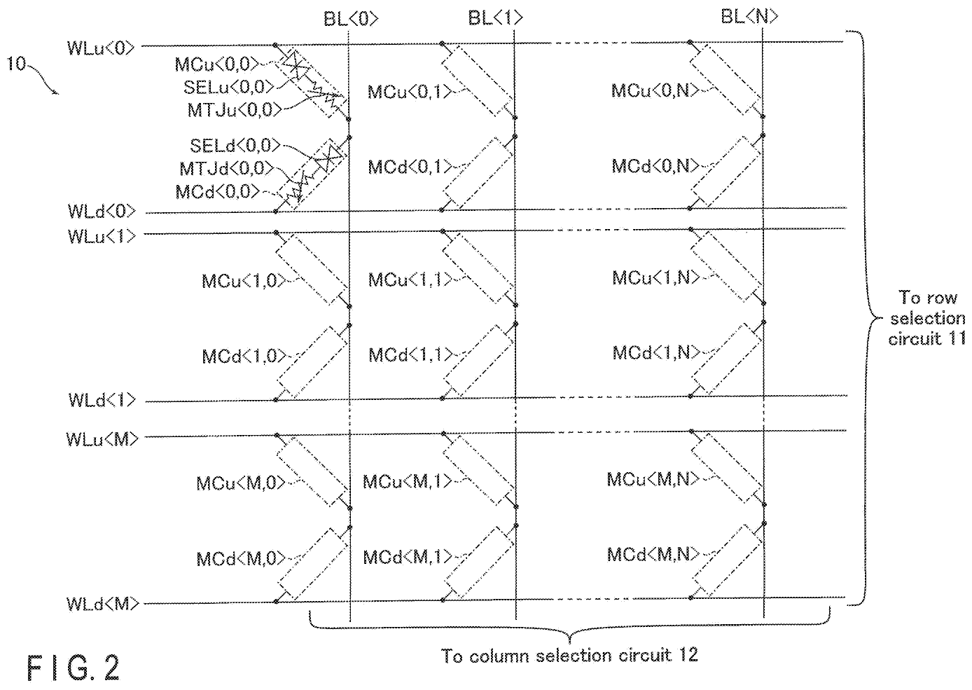

Next, a configuration of the memory cell array of the magnetic memory device according to the embodiment will be described with reference to FIG. 2. FIG. 2 is a circuit diagram showing a configuration of the memory cell array of the magnetic memory device according to the embodiment. In FIG. 2, the word lines WL are classified by suffixes, each including one of two lower-case alphabetical letters (“u” and “d”) and an index (“< >”).

As shown in FIG. 2, the memory cells MC (MCu and MCd) are arranged in a matrix pattern in the memory cell array 10, with each memory cell MC associated with a pair of one of the bit lines BL (BL<0>, BL<1>, . . . , BL<N>) and one of the word lines WLd (WLd<0>, WLd<1>, . . . , WLd<M>) and WLu (WLu<0>, WLu<1>, . . . , WLu<M>), where M and N are any integers. That is, a memory cell MCd<i,j> (0≤i≤M and 0≤j≤N) is coupled between a word line WLd<i> and a bit line BL<j>, and a memory cell MCu<i,j> is coupled between a word line WLu<i>and a bit line BL<j>.

The suffixes “a” and “u” are attached for the convenience of distinction between, for example, upper memory cells MC and lower memory cells MC (with respect to bit lines BL, for example) among a plurality of memory cells MC. An example of the three-dimensional structure of the memory cell array 10 will be discussed later. The memory cell MCd<i,j> includes a switching element SELd<i,j> and a magnetoresistance effect element MTJd<i,j>, which are coupled in series to each other. The memory cell MCu<i,j > includes a switching element SELu<i,j> and a magnetoresistance effect element MTJu<i,j>, which are coupled in series to each other.

The switching element SEL functions as a switch for controlling supply of a current to the corresponding magnetoresistance effect element MTJ when data is written in or read from the magnetoresistance effect element MTJ. Specifically, a switching element SEL in a memory cell MC serves as an insulator with a large resistance value and interrupts a current (i.e., is turned off) when the voltage applied to the memory cell MC falls below a threshold voltage Vth, and serves as a conductor with a low resistance value and allows a current to pass therethrough (i.e., is turned on) when the voltage applied to the memory cell MC exceeds the threshold voltage Vth. That is, the switching element SEL has a function of switching between allowance and interruption of a current flow according to the magnitude of the voltage applied to the memory cell MC, regardless of the direction of the current flow.

The switching element SEL may be, for example, a two-terminal switching element. When a voltage applied between the two terminals is lower than a threshold, the switching element is in a “high resistance” state, such as an electrically non-conductive state. When a voltage applied between the two terminals is equal to or higher than the threshold, the switching element is in a “low-resistance” state, such as an electrically conductive state. The switch element may have this function regardless of the polarity of the voltage.

The magnetoresistance effect element MTJ can be switched between the low-resistance state and the high-resistance state by its resistance value being changed by current supply controlled by the switching element SEL. The magnetoresistance effect element MTJ functions as a memory element Which allows data to be: written therein by its resistance state being changed, nonvolatilely stores the written data, and allows the written data to be read therefrom.

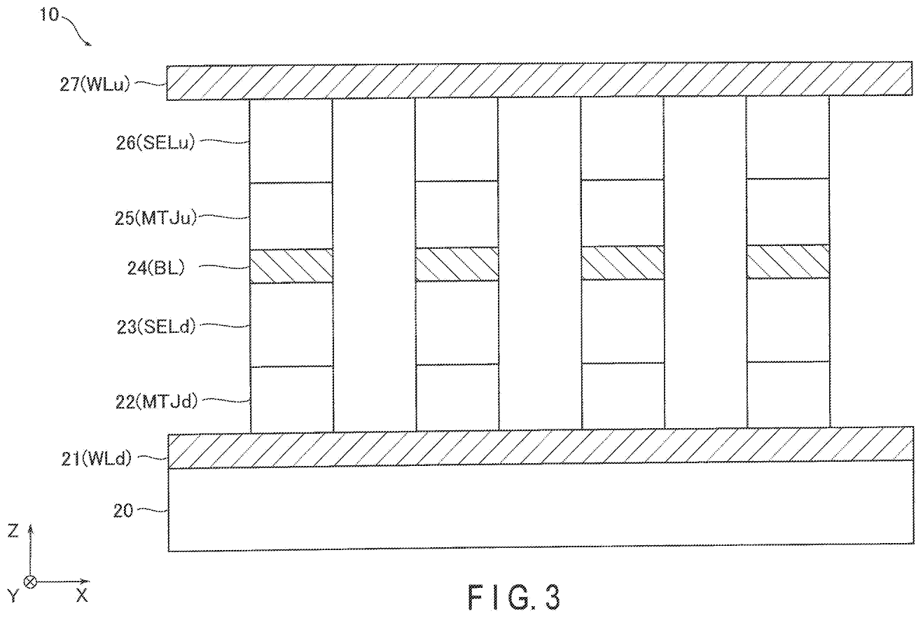

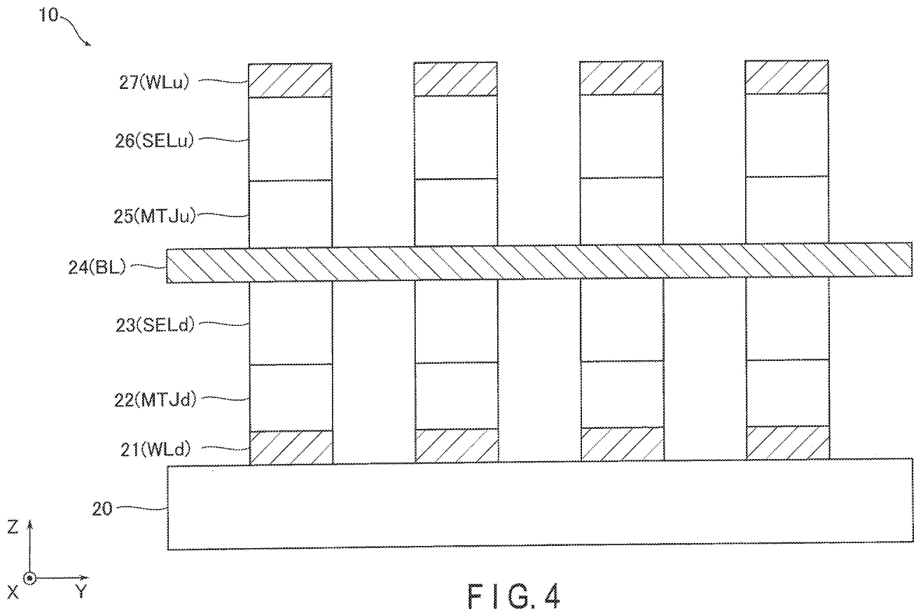

Next, a cross-sectional structure of the memory cell array 10 will be described with reference to FIGS. 3 and 4. FIGS. 3 and 4 each show an example of a cross-sectional view illustrating a configuration of the memory cell array of the Magnetic Memory device according to the embodiment. FIGS. 3 and 4 are cross-sectional views of the memory array 10 viewed in different directions orthogonal to each other.

As shown in FIGS. 3 and 4, the memory cell array 10 is provided on a semiconductor substrate 20. In the following description, a plane parallel to a surface of the semiconductor substrate 20 will be referred to as an “XY plane”, and an axis perpendicular to the XY plane will be referred to as a “Z-axis”. On the XY plane, an axis extending along the word lines WL will be referred to as an “X-axis”, and an axis extending along the bit lines BL will be referred to as a “Y-axis”. That is, FIGS. 3 and 4 are cross-sectional views of the memory cell array 10 viewed in the Y-axis direction and the X-axis direction, respectively.

For example, a plurality of conductors 21 are provided on an upper surface of the semiconductor substrate 20. The conductors 21 are conductive, and function as word lines WLd. The conductors 21 are, for example, aligned along the Y-axis and extend, along the X-axis. In FIGS. 3 and 4, the conductors 21 are provided on the semiconductor substrate 20; however, the configuration is not limited to this. For example, the conductors 21 may be provided above the semiconductor substrate 20, without being in contact with the semiconductor substrate 20.

On an upper surface of each conductor 21, a plurality of elements 22, each of which functions as a magnetoresistance effect element MTJd, are provided. The elements 22 provided on the upper surface of each conductor 21 are, for example, aligned along the X-axis. That is, a plurality of elements 22 aligned along the X-axis are coupled in common to an upper surface of one conductor 21. The configuration of the element 22 will be described in detail later.

A plurality of elements 23, which function as switching elements SELd, are respectively provided on the upper surfaces of the elements 22. The upper surfaces of the elements 23 are each coupled to one of a plurality of conductors 24. The conductors 24 are conductive, and function as bit lines BL. The conductors 24 are, for example, aligned along the X-axis and extend along the Y-axis. That is, a plurality of elements 23 aligned along the Y-axis are coupled in common to one conductor 24. In FIGS. 3 and 4, the elements 23 are in contact with the upper surfaces of the elements 22 and in contact with the lower surfaces of the conductors 24; however, the configuration is not limited to this. For example, the elements 23 may be coupled to the respective elements 22 and the respective conductors 24 via conductive contact plugs (not shown).

On the upper surface of each conductor 24, a plurality of elements 25, which function as magnetoresistance effect elements MTJu, are provided. The elements 25 provided on the upper surface of each conductor 24 are, for example, aligned along the Y-axis. That is, a plurality of elements 25 aligned along the Y-axis are coupled in common to an upper surface of one conductor 24. Each element 25 has a configuration similar to, for example, that of the element 22.

A plurality of elements 26, which function as switching elements SELu, are respectively provided on the upper surfaces of the elements 25. The upper surfaces of the elements 26 are each coupled to one of a plurality of conductors 27. The conductors 27 are conductive, and function as word lines WLu. The conductors 27 are, for example, aligned along the Y-axis and extend along the X-axis. That is, a plurality of elements 26 aligned along the X-axis are coupled in common to one conductor 27. In FIGS. 3 and 4, the elements 26 are in contact with the upper surfaces of the elements 25 and in contact with the lower surfaces of the conductors 27; however, the configuration is not limited to this. For example, the elements 26 may be coupled to the respective elements 25 and the respective conductors 27 via conductive contact plugs (not shown).

Accordingly, the memory ceil array 10 has a configuration in which a pair of word lines WLd and WLu corresponds to one bit line BL. In the memory cell array 10, a memory cell MCd is provided between a word line WLd and a bit line BL, and a memory cell MCu is provided between a bit line BL and a word line WLu. That is, the memory cell array 10 has a structure in which a plurality of memory cells MC are provided at different Z-axis levels. In the cell structure shown in FIGS. 3 and 4, memory cells MCd correspond to a lower layer, and memory cells MCu correspond to an upper layer. That is, of two memory cells MC coupled in common to one bit line BL, the memory cell MC provided in the upper layer with respect to the bit line BL corresponds to the memory cell MCu, which is accompanied by the suffix “u”, and the memory cell MC provided in the lower layer with respect to the bit line BL corresponds to the memory cell MCd, which is accompanied by the suffix “d”.

1.1.3 Magnetoresistive Effect Element

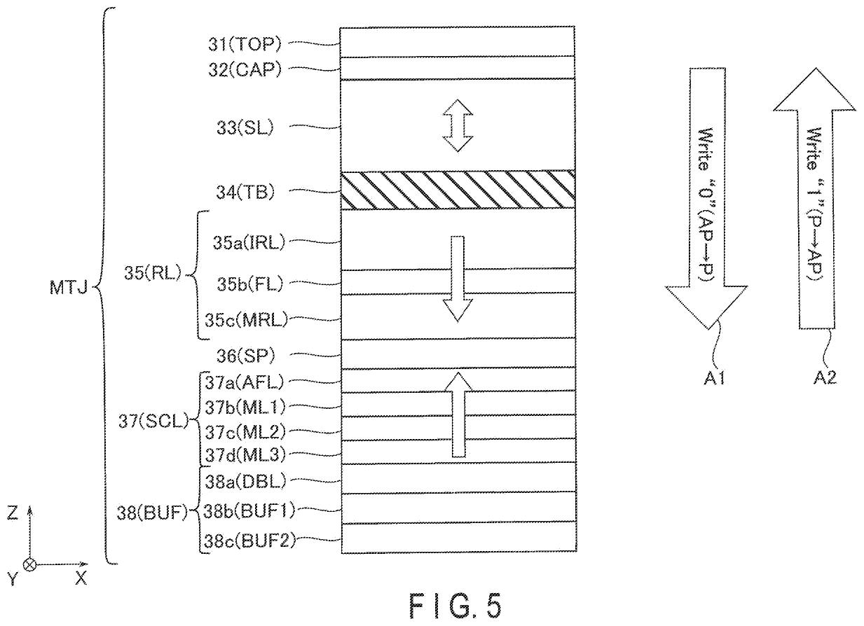

Next, a configuration of the magnetoresistance effect element of the magnetic memory device according to the embodiment will be described with reference to FIG. 5. FIG. 5 is a cross-sectional view showing a configuration of the magnetoresistance effect element of the magnetic memory device according to the embodiment. FIG. 5 shows an example of a cross section of the magnetoresistance effect element MTJd shown in, for example, FIGS. 3 and 4, taken along a plane perpendicular to the Z-axis (e.g., the XZ plane). Since the magnetoresistance effect element MTJu has a configuration similar to that of the magnetoresistance effect element MTJd, a drawing thereof is omitted.

As shown in FIG. 5, the magnetoresistance effect element MTJ includes, for example, a non-magnetic layer 31 which functions as a top layer TOP, a non-magnetic layer 32 which functions as a capping layer CAP, a ferromagnetic layer 33 which functions as a storage layer SL, a non-magnetic layer 34 which functions as a tunnel barrier layer TB, a layer stack 35 which functions as a reference layer RL, a non-magnetic layer 36 which functions as a spacer layer SP, a layer stack 37 which functions as a shift canceling layer SCL, and a layer stack 39 which functions as a buffer layer BUF. Each of the storage layer SL, the reference layer RL, and the shift canceling layer SCL may be regarded as a ferromagnetic structure as a whole. The buffer layer BUF may be regarded as a non-magnetic structure as a whole.

The magnetoresistance effect element MTJd includes a plurality of films stacked in the order of, from the word line WLd side to the bit line BL side (in the Z-axis direction), the layer stack 38, the layer stack 37, the non-magnetic layer 36, the layer stack 35, the non-magnetic layer 34, the ferromagnetic layer 33, the non-magnetic layer 32, and the non-magnetic layer 31, for example. The magnetoresistance effect element MTJu includes a plurality of films stacked in the order of, from the bit line BL side to the word line WLu side (in the Z-axis direction), the layer stack 38, the layer stack 37, the non-magnetic layer 36, the layer stack 35, the non-magnetic layer 34, the ferromagnetic layer 33. the non-magnetic layer 32, and the non-magnetic layer 31, for example. The magnetoresistance effect elements MTJd and MTJu function as MTJ elements of a perpendicular magnetic recording type, in which, for example, the magnetization directions of magnetic bodies constituting the magnetoresistance effect elements MTJd and MTJu are perpendicular to the film surfaces. The magnetoresistance effect element MTJ may include further layers (not shown) between the layers 31 to 33.

The non-magnetic layer 31 is a non-magnetic conductor, and functions as a top electrode that, improves electrical connectivity between the upper end of the magnetoresistance effect element MTJ and the bit line BL or word line WL. The non-magnetic layer 31 contains at least one element or compound selected from, for example, tungsten (W), tantalum (Ta), tantalum nitride (TaN), titanium (Ti), and titanium nitride (TiN).

The non-magnetic layer 32 is a layer of a nonmagnet, and has a function of suppressing an increase of the damping constant of the ferromagnetic layer 33 and reducing the write current. The non-magnetic layer 32 contains, for example, magnesium oxide (MgO), aluminum oxide (Al₂O₃), or rare-earth oxide. Alternatively, the non-magnetic layer 32 may be a mixture of these oxides. That is, the non-magnetic layer 32 does not necessarily contain a binary compound consisting of two types of elements, but may contain a ternary compound consisting of three types of elements, such as magnesium aluminum oxide (MgAl₂O₄) .

The ferromagnetic layer 33 is ferromagnetic, and has an easy magnetization axis in a direction perpendicular to the film surface. The ferromagnetic layer 33 has a magnetization direction along the Z-axis, directed toward either the bit line BL side or the word line WL side. The ferromagnetic layer 33 contains iron (Fe), and may further contain at least one of cobalt (Co) and nickel (Ni). The ferromagnetic layer 33 may further contain boron (B). Specifically, the ferromagnetic layer 33 may contain, for example, iron cobalt boron (FeCoB) or iron boride (FeB), and have a body-centered cubic crystal structure.

The non-magnetic layer 34 is a non-magnetic insulator and contains, for example, magnesium oxide (MgO). The non-magnetic layer 34 has a NaCl crystal structure with its film surface oriented in the (001) plane, and functions as a seed material which serves as the nucleus for growing a crystalline film from the interface with the ferromagnetic layer 33 in the crystallizing process of the ferromagnetic layer 33. The non-magnetic layer 34 is provided between the ferromagnetic layer 33 and the layer stack 35, and forms a magnetic tunnel junction together with these two ferromagnetic layers.

The layer stack 35 can be regarded as a single ferromagnetic layer as a whole, and has an easy magnetization axis in a direction perpendicular to the film surface. The layer stack 35 has a magnetization direction along the Z-axis, directed toward either the bit line BL side or the word line WL side. The layer stack 35 has a fixed magnetization direction. In the example of FIG. 5, the magnetization direction is directed toward the layer stack 37. The “magnetization direction” being “fixed” means that the magnetization direction is not changed by a current (spin torque) large enough to reverse the magnetization direction of the ferromagnetic layer 33.

Specifically, the layer stack 35 includes a ferromagnetic layer 35a which functions as an interface layer IL, a non-magnetic layer 35b which functions as a function layer FL, and a ferromagnetic layer 35c which functions as a main reference layer MRL. For example, the ferromagnetic layer 35c, the non-magnetic layer 35b, and the ferromagnetic layer 35a are stacked in the order of appearance between the upper surface of the non-magnetic layer 36 and the lower surface of the non-magnetic layer 34.

The ferromagnetic layer 35a is a ferromagnetic conductor, and contains, for example, iron (Fe) and may further contain at least one of cobalt (Co) and nickel (Ni). The ferromagnetic layer 35a may further contain boron (B). Specifically, the ferromagnetic layer 35a may contain, for example, iron cobalt boron (FeCoB) or iron boride (FeB), and have a body-centered cubic crystal structure.

The non-magnetic layer 35b is a non-magnetic conductor, and contains at least one metal selected from, for example, tantalum (Ta), hafnium (Hf), tungsten (W), zirconium (Zr), molybdenum (Mo), niobium (Nb), and titanium (Ti). The non-magnetic layer 35b has a function of maintaining exchange coupling between the ferromagnetic layer 35a and the ferromagnetic layer 35c.

The ferromagnetic layer 35c may include at least one multi-layer selected from, for example, a multi-layer of cobalt (Co) and platinum (Pt) (Co/Pt multi-layer), a multi-layer of cobalt (Co) and nickel (Ni) (Co/Ni multi-layer), and a multi-layer of cobalt (Co) and palladium (Pd) (Co/Pd multi-layer). Of the multi-layers constituting the ferromagnetic layer 35c, the layer in contact with the non-magnetic layer 36 contains, for example, cobalt (Co).

The non-magnetic layer 36 is a non-magnetic conductor, and contains at least one element selected from, for example, ruthenium (Ru), osmium (Os), rhodium (Rh), iridium (Ir), vanadium (V), and chromium (Cr).

The layer stack 37 can be regarded as a single ferromagnetic layer as a whole, and has an easy magnetization axis in a direction perpendicular to the film surface. The layer stack 37 has a magnetization direction along the Z-axis, directed toward either the bit line BL side or the word line WL side. Like the layer stack 35, the layer stack 37 has a fixed magnetization direction. In the example of FIG. 5, the magnetization direction is directed toward the layer stack 35.

Specifically, the layer stack 37 includes a ferromagnetic layer 37a which functions as an antiferromagnetic coupling layer AFL, and a non-magnetic layer 37b(ML1), ferromagnetic layer 37c(ML2), and non-magnetic layer 37d(ML3)r each of which functions as a multi-layer ML. For example, the non-magnetic layer 37d, the ferromagnetic layer 37c, the non-magnetic layer 37b, and the ferromagnetic layer 37a are stacked in the order of appearance between the upper surface of the layer stack 38 and the lower surface of the non-magnetic layer 36. The ferromagnetic layer 37a is a ferromagnetic conductor having a hexagonal close-packed (hcp) structure or face-centered cubic (fcc) crystal structure, and contains, for example, cobalt (Co). The ferromagnetic layers 35c and 37a are antiferromagnetically coupled to each other by the non-magnetic layer 36. In other words, the ferromagnetic layer 35c (in particular, the multi-layer in contact with the non-magnetic layer 36 among the multi-layers constituting the ferromagnetic layer 35c) and the ferromagnetic layer 37a are coupled so as to have magnetization directions that are antiparallel to each other. Accordingly, the magnetization directions of the ferromagnetic layers 35c and 37a are directed to each other in the example of FIG. 5. Such a coupling structure of the ferromagnetic layer 35c, the non-magnetic layer 36, and the ferromagnetic layer 37a is referred to as a synthetic antiferromagnetic (SAF) structure.

The non-magnetic layer 37b is a non-magnetic conductor, and contains at least one element selected from, for example, platinum (Pt), nickel (Ni), and palladium (Pd). The ferromagnetic layer 37c is a ferromagnetic conductor, and contains, for example, cobalt (Co). The non-magnetic layer 37d is a non-magnetic conductor, and contains at least one element selected from, for example, platinum (Ft) ( nickel (Ni), and palladium (Pd).

The ferromagnetic layers 37a and 37c and the non-magnetic layers 37b and 37d further contain silicon (Si) or germanium (Ge). Accordingly, the layer stack 37 has properties of suppressing diffusion of iron (Fe) contained in, for example, the ferromagnetic layer 35a to the SAF structure in a high-temperature environment such as annealing process. In the following description, an element, such as iron (Fe) mentioned above, which easily diffuses in annealing process will also be referred to as an “easily diffusible element”. An element, such as silicon (Si) or germanium (Ge) mentioned above, which has a function of suppressing diffusion of easily diffusible elements to another layer will be called a “diffusion suppression element”.

In the example of FIG. 5, two pairs of a ferromagnetic layer and a non-magnetic layer are stacked in the layer stack 37; however, three or mere pairs of a ferromagnetic layer and a non-magnetic layer may be stacked. In other words, each of stacked multiple pairs of a ferromagnetic layer and a non-magnetic layer may constitute at least one multi-layer selected from a multi-layer of cobalt (Co) and platinum (Pt) (Co/Pt multi-layer), a multi-layer of cobalt (Co) and nickel (Ni) (Co/Ni multi-layer), and a multi-layer of cobalt (Co) and palladium (Pd) (Co/Pd multi-layer).

With the above configuration, the layer stack 37 can cancel the influence of the stray field from the layer stack 35 on the magnetization direction of the ferromagnetic layer 33. This can suppress the occurrence of asymmetry in the ease of reversal of magnetization direction of the ferromagnetic layer 33 due to the stray field, etc. from the layer stack 35 (i.e., the ease of reversal when the magnetization direction of the ferromagnetic layer 33 differing between a rotation in one direction and a rotation in an opposite direction).

The layer stack 38 can be regarded as one non-magnetic layer as a whole, and functions as an electrode that improves electrical connectivity with the bit line BL or word line WL. Specifically, the layer stack 38 includes a non-magnetic layer 38a which functions as a diffusion barrier layer, and a non-magnetic layer 38b(BUF1) and non-magnetic layer 38c(BUF2), each of which functions as a buffer layer BUF. For example, the non-magnetic layer 38c, the non-magnetic layer 38b, and the non-magnetic layer 38a are stacked along the X axis in the order of appearance between the semiconductor substrate 20 and the lower surface of the layer stack 37.

The non-magnetic layer 38a is a non-magnetic conductor having an amorphous structure, and contains, for example, silicon (Si) or germanium (Ge), which functions as a diffusion suppression element. The non-magnetic layer 38a also contains boron (B). The non-magnetic layer 38a functions as a supply source for supplying diffusion suppression elements into the layer stack 37 in a film forming process (i.e., a process preceding the annealing process). This enables the layer stack 37 to exhibit the properties of suppressing diffusion of iron (Fe) contained in, for example, the ferromagnetic layer 35a to the SAP structure, prior to annealing process.

The non-magnetic layer 38b is a non-magnetic conductor, and contains, for example, tantalum (Ta) or molybdenum (Mo). The non-magnetic layer 38b has a function of improving the tunnel magnetoresistive ratio (TMR) of the magnetic tunnel junction formed by the ferromagnetic layer 33, the non-magnetic layer 34, and the ferromagnetic layer 35a.

The non-magnetic layer 38c is a non-magnetic conductor having an amorphous structure, and contains, for example, hafnium (Hf) or hafnium boride (HfB). The non-magnetic layer 38c has a function of separating the crystal structures of the upper layers of the non-magnetic layer 38c from the crystal structures of the lower layers of the non-magnetic layer 38c.

The non-magnetic layers 38b and 38c may be omitted as appropriate in accordance with materials included in the lower layers of the layer stack 38 (such as the conductor 21 and the semiconductor substrate 20).

The embodiment adopts a spin injection write technique of directly feeding a write current to the magnetoresistance effect element MTJ as described above, injecting a spin torque into the storage layer SL and the reference layer RL by the write current, and controlling the magnetization directions of the storage layer SL and the reference layer RL. The magnetoresistance effect element MTJ may assume either a low-resistance state or a high-resistance state, depending on whether the relative relationship between the magnetization directions of the storage layer SL and the reference layer RL is parallel or antiparallel.

When a write current Ic0 of a certain magnitude is fed to the magnetoresistance effect element MTJ in the direction of the arrow A1 in FIG. 5, i.e., the direction from the storage layer SL toward the reference layer RL, the relative relationship between the magnetization directions of the storage layer SL and the reference layer RL becomes parallel. In this parallel state, the resistance of the rnagnetoresistance effect element MTJ takes the minimum value, and the magnetoresistance effect element MTJ is set to the low-resistance state. This low-resistance state is called a “parallel (P) state”, and is defined as, for example, the state of data “0”.

When a write current Ic1 of a magnitude greater than that of the write current Ic0 is fed to the magnetoresistance effect element MTJ in the direction of the arrow A2 in FIG. 5, i.e., the direction from the reference layer RL toward the storage layer SL (direction opposite to the arrow A1), the relative relationship between the magnetization directions of the storage layer SL and the reference layer RL becomes antiparallel. In this antiparallel state, the resistance of the magnetoresistance effect element MTJ takes the maximum value, and the magnetoresistance effect element MTJ is set to the high-resistance state. This high-resistance state is called an “antiparallel (AP) state”, and is defined as, for example, the state, of data “1”.

The following description will be given in accordance with the above-described data definition; however, the definition of data “1” and data “0” is not limited thereto. For example, the P state may be defined as the state of data “1”, and the AP state may be defined as the state of data “0”.

1.2 Method of Manufacturing Magnetoresistive Effect Element

Next, a method of manufacturing the magnetoresistance effect element of the magnetic memory device according to the embodiment will be described. The manufacturing method will be described particularly as to the layers from the layer stack 38 (buffer layer BUF) to the layer stack 35 (reference layer RL) of the constituent elements of the magnetoresistance effect element MTJ, and a description as to the non-magnetic layer 34 and the layers thereabove will be omitted.

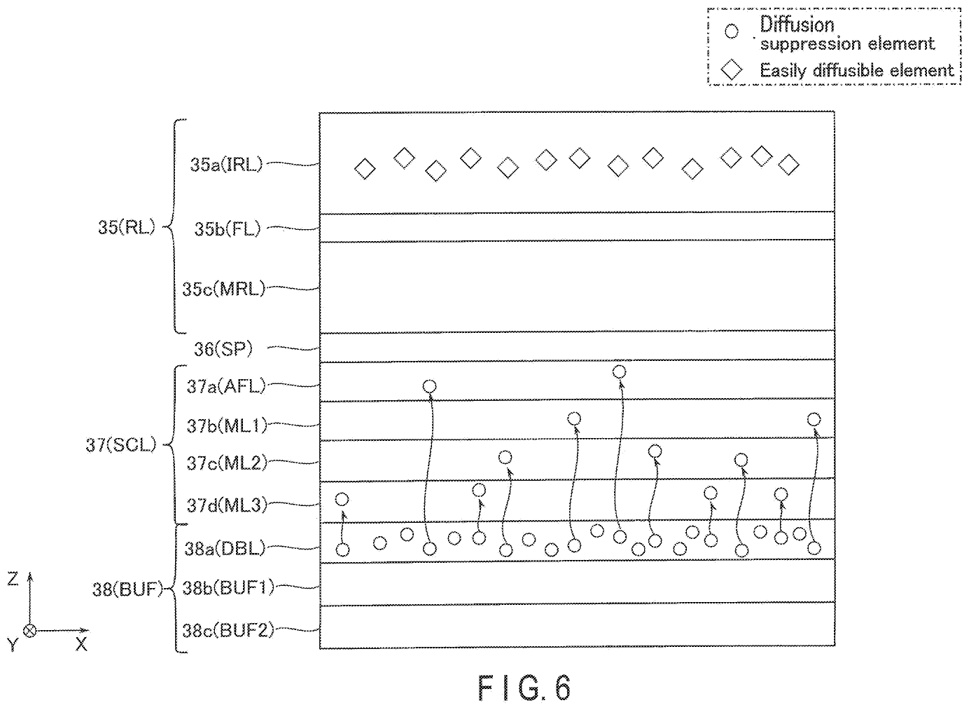

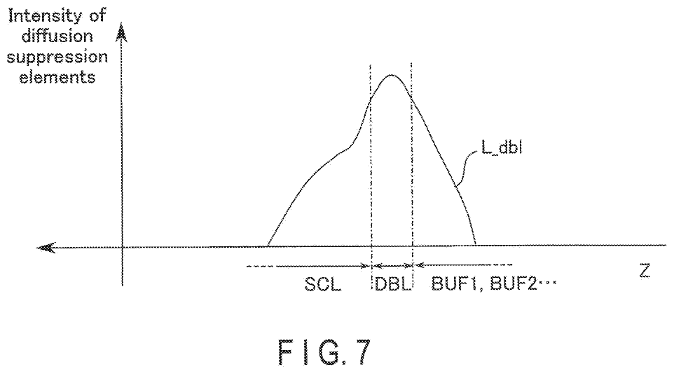

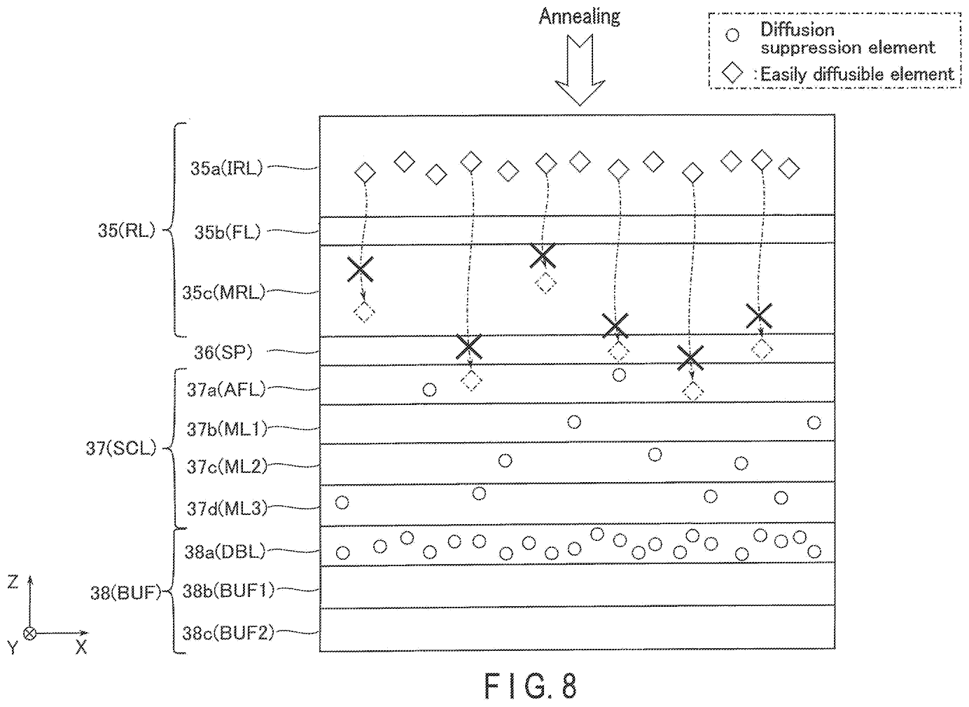

FIGS. 6 and 8 are schematic diagrams illustrating the method of manufacturing the magnetoresistance effect element of the magnetic memory device according to the embodiment. FIGS. 6 and 8 show a layer structure before and after annealing process, which is to function as a magnetoresistance effect element MTJ. FIG. 7 is a diagram showing distribution of diffusion suppression elements in the magnetoresistance effect element of the magnetoresistive memory device according to the embodiment before annealing process. In FIG. 7, the horizontal axis corresponds to the Z-axis, the vertical axis corresponds to the intensity of diffusion suppression elements, and the distribution of diffusion suppression elements in the magnetoresistance effect element MTJ is indicated as line L_dbl. The distribution shown in FIG. 7 can be measured by, for example, secondary ion mass spectrometry (SIMS).

As shown in FIG. 6, the non-magnetic layer 38c, the non-magnetic layer 38b, the non-magnetic layer 38a, the non-magnetic layer 37d, the ferromagnetic layer 37c, the non-magnetic layer 37b, the ferromagnetic layer 37a, the non-magnetic layer 36, the ferromagnetic layer 35c, the non-magnetic layer 35b, and the ferromagnetic layer 35a are stacked in the order of appearance above the semiconductor substrate 20.

As described above, the non-magnetic layer 38a contains silicon (Si) or germanium (Ge) as diffusion suppression elements (represented by circles in FIG. 6). In contrast, the ferromagnetic layer 35a contains iron (Fe) as an element having the property of easily diffusing into another layer in a high-temperature environment (represented by diamonds in FIG. 6).

As shown in FIG. 7, diffusion suppression elements in the non-magnetic layer 33a diffuse mainly into the layer stack 37, i.e., upper layers, after the layers are formed and before annealing process is performed. Accordingly, diffusion suppression elements are supplied to the ferromagnetic layers 37a and 37c and the non-magnetic layers 37b and 37d. A concentration of diffusion suppression elements in the non-magnetic layer 38a is higher than a concentration of diffusion suppression elements in the layer stack 37, a concentration of diffusion suppression elements in the non-magnetic layer 38b, and a concentration of diffusion suppression elements in the non-magnetic layer 38c.

Next, as shown in FIG. 8, annealing process is performed on the layer structure shown in FIG. 6, and the layer structure can obtain the properties of a magnetoresistance effect element MTJ.

With heat externally applied to the layers through annealing process, the easily diffusible elements in the ferromagnetic layer 35a may diffuse into other layers. Easily diffusible elements may lower the coupling force of antiferromagnetic coupling between the reference layer RL and the shift canceling layer SCL by diffusing into, for example, the SAF structure, i.e., the ferromagnetic layer 35c, the non-magnetic layer 36, and the ferromagnetic layer 37a. The lowering of the coupling force of the antiferromagnetic coupling causes lowering of stability of the magnetization direction of the reference layer RL, and thus is not preferable.

According to the embodiment, the layer stack 37 is supplied with diffusion suppression elements from the non-magnetic layer 38a before annealing process. Therefore, the layer stack 37 is provided with a function of suppressing diffusion of easily diffusible elements in the ferromagnetic layer 35a into the SAF structure. This enables suppression of inclusion of easily diffusible elements into the SAF structure as impurities. Consequently, deterioration of performance of the magnetoresistance effect element MTJ can be suppressed.

1.3 Advantageous Effects of Present Embodiment

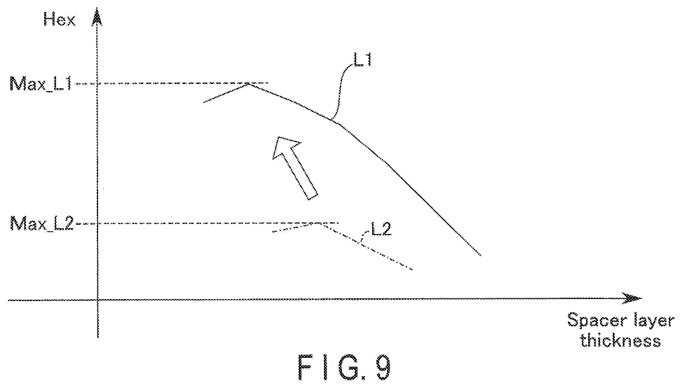

The embodiment enables manufacturing of a magnetoresistance effect element MTJ while suppressing deterioration of performance of the magnetoresistance effect element MTJ. This advantageous effect will be described with reference to FIG. 9.

FIG. 9 is a diagram illustrating advantageous effects of the embodiment. In FIG. 9, lines L1 and L2 are plotted with the horizontal axis representing the thickness of the spacer layer SP (i.e., the non-magnetic layer 36), and the vertical axis representing the index Hex corresponding to the magnitude of the external magnetic field required to reverse the magnetization direction of the interference layer IL. The line L1 corresponds to the index Hex or the magnetoresistance effect element MTJ of the embodiment, and the line L2 corresponds to the index Hex of a magnetoresistance effect element MTJ of a comparative example. The magnetoresistance effect element MTJ of the comparative example does not include, for example, the non-magnetic layer 38a.

As shown in FIG. 9, the index Hex changes depending on the thickness of the spacer layer SP, and takes the maximum value when the spacer layer SP has the optimal thickness. The maximum value of the index Hex may decrease under the influence of impurities included in the spacer layer SP, and the main reference layer MRL and the antiferromagnetic coupling layer AFL in the shift canceling layer SCL, which constitute the SAF structure together with the spacer layer SP. Namely, to attain an ideal value as the maximum value of the index Hex, it is preferable to reduce the amount of impurities in the SAF structure which inhibit anti ferromagnetic coupling in the SAF structure.

As described above, the magnetoresistance effect element of the comparative example does not include the non-magnetic layer 38a. Accordingly, the layer stack 37 of the comparative example is not supplied with diffusion suppression elements, such as silicon (Si) or germanium (Ge). Therefore, many of the easily diffusible elements, such as iron (Fe), contained in the ferromagnetic layer 33 and ferromagnetic layer 35a diffuse into the SAF structure at the time of annealing process, and the coupling force of the antiferromagnetic coupling decreases.

In contrast, the magnetoresistance effect element of the embodiment includes the non-magnetic layer 38a. Accordingly, the layer stack 37 of the embodiment is supplied with diffusion suppression elements, such as silicon (Si) or germanium (Ge), prior to annealing process. This can reduce the number of easily diffusible elements, such as iron (Fe), which diffuse from the ferromagnetic layer 33 and ferromagnetic layer 35a into the SAF structure at the time of annealing process, and can suppress a decrease in the coupling force of the antiferromagnetic coupling.

Consequently, it is possible to make the maximum value Max_L1 of the index Hex in the embodiment larger than the maximum value Max_L2 of the index Hex in the comparative example. Since a larger index Hex can be obtained, the memory cells MC can be operated with a smaller write current Ic. Therefore, deterioration of performance of the magnetoresistance effect element MTJ can be suppressed.

To improve the tunnel magneto-resistance ratio TMR, it is preferable to apply a larger amount of heat to the magnetoresistance effect element MTJ at the time of annealing process. However, if a large amount of heat is applied, the coupling force of the antiferromagnetic coupling in the SAF structure may decrease, and the index Hex may decrease. In this way, the amount of heat applied at the time of annealing process may be determined based on the trade-off between improvement of the tunnel magneto-resistance ratio TMR and suppression of a decrease in the index Hex. According to the embodiment, a larger index Hex can be obtained. Therefore, the restriction on the amount of heat applied at the time of annealing process can be alleviated (namely, heat resistance can be improved).

2 Modifications

The above-described embodiment is merely an example, and can be modified in various manners.

For example, the memory cell MC in the above embodiment employs a two-terminal switching element as the switching element SEL; however, a metal-oxide-semiconductor (MCS) transistor may be employed as the switching element SEL. That is, the memory cell array does not necessarily have the structure including a plurality of memory cells MC at different Z-directional levels, and may have any other array structure.

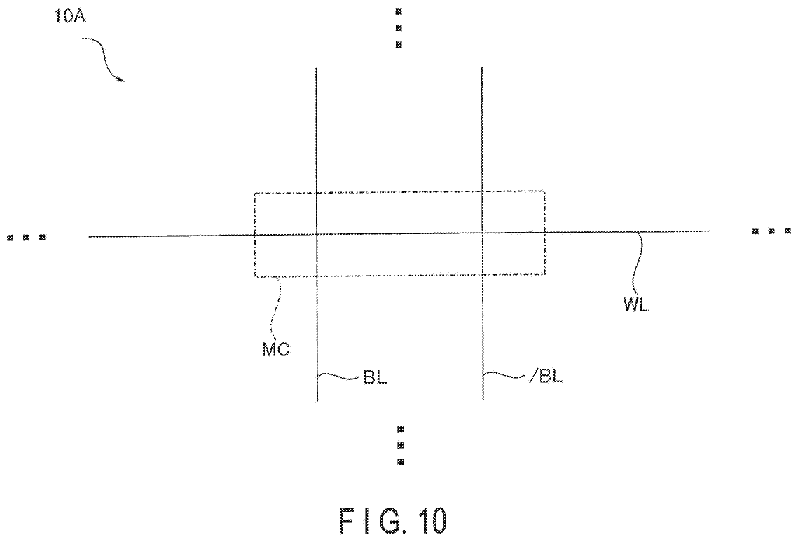

FIG. 10 is a circuit diagram illustrating a configuration of a memory cell array of a magnetic memory device according to a modification. FIG. 10 corresponds to the memory cell array 10 of the magnetic memory device 1 described in the embodiment with reference to FIG. 1.

As shown in FIG. 10, a memory cell array 10A includes a plurality of memory cells MC each associated with a row and a column. Memory cells MC in the same row are coupled to the same word line WL, and both ends of memory cells MC in the same column are coupled to the same bit line BL and the same source line /BL.

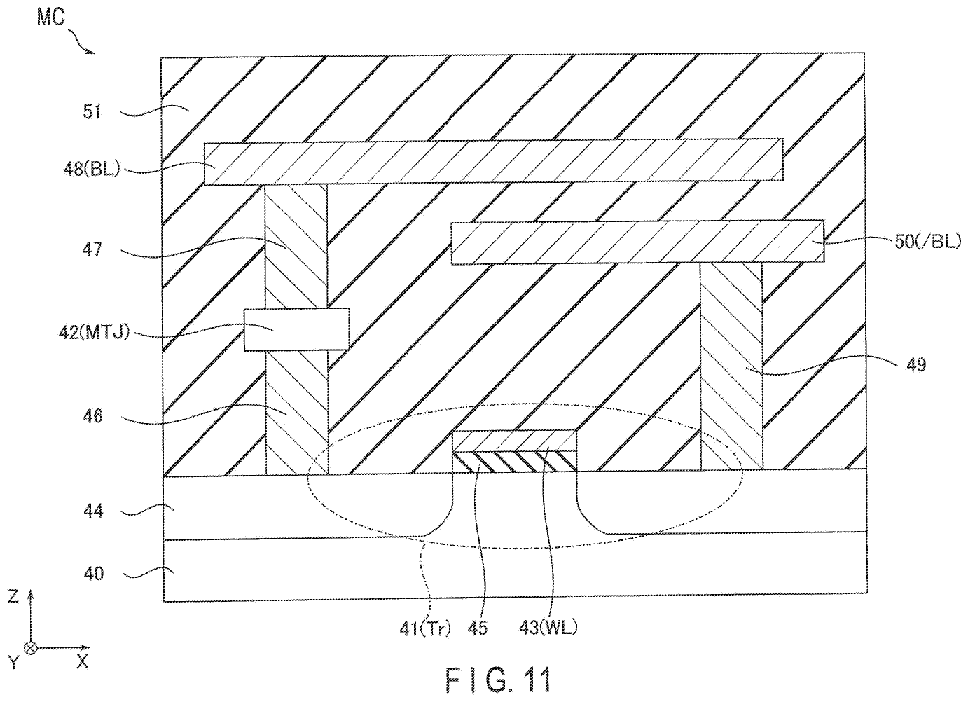

FIG. 11 is a cross-sectional view illustrating a configuration of a memory cell of the magnetic memory device according to the modification. FIG. 11 corresponds to the memory cell MC described in the embodiment with reference to FIGS. 3 and 4. In the example of FIG. 11, memory cells MC are not stacked on the semiconductor substrate; therefore, suffixes such as “d” and “u” are not added.

As shown in FIG. 11, a memory cell MC is provided on a semiconductor substrate 40, and includes a select transistor 41 (Tr) and a magnetoresistance effect element 42 (MTJ). The select transistor 41 is provided as a switch that controls supply and interruption of a current when data is written in or read from the magnetoresistance effect element 42. The configuration of the magnetoresistance effect element 42 is similar to that of the magnetoresistance effect element MTJ of the embodiment shown in FIG. 5.

The select transistor 41 includes a gate (conductor 43) which functions as a word line WL, and a pair of source and drain regions (a diffusion region 44) provided on the semiconductor substrate 40 at both ends of the gate on the X-axis. The conductor 43 is provided on an insulator 45 which is provided on the semiconductor substrate 40 and functions as a gate insulating film. The conductor 43, for example, extends along the Y-axis, and is coupled in common to gates of select transistors (not shown) of other memory cells MC aligned along the Y-axis. Conductors 43 are aligned along, for example, the X-axis. A contact plug 46 is provided on the diffusion region 44 provided at a first end of the select transistor 41. The contact plug 46 is coupled onto a lower surface (first end) of the magnetoresistance effect element 42. A contact plug 47 is provided on an upper surface (second end) of the magnetoresistance effect element 42, and a conductor 48, which functions as a bit line BL, is coupled to an upper surface of the contact plug 47. The conductor 48, for example, extends along the X-axis, and is coupled in common to second ends of magnetoresistance effect elements (not shown) of other memory cells aligned along the X-axis. A contact plug 49 is provided on the diffusion region 44 provided at a second end of the select transistor 41. The contact plug 49 is coupled onto a lower surface of a conductor 50 which functions as a source line /BL. The conductor 50, for example, extends along the X-axis, and is coupled in common to second ends of select transistors (not shown) of other memory cells aligned along the X-axis. Conductors 48 and 50 are aligned along, for example, the Y-axis. The conductor 48 is positioned, for example, above the conductor 50. The conductors 48 and 50 are arranged so as to avoid physical and electrical interference from each other, although not shown in FIG. 11. The select transistor 41, the magnetoresistance effect element 42, the conductors 43, 48 and 50, and the contact plugs 46, 47 and 49 are covered with an interlayer insulating film 51. The magnetoresistance effect element 42 and other magnetoresistance effect elements (not shown) aligned with the magnetoresistance effect element 42 along the X-axis or the Y-axis are provided on, for example, the same level. That is, a plurality of magnetoresistance effect elements 42 are arranged, for example, on the XY plane in the memory cell array 10A.

With the above-described configuration, even when a MOS transistor, which is a three-terminal switching element, is employed as the switching element SEL, instead of a two-terminal switching element, advantageous effects similar to those of the embodiment can be produced.

3 Others

In the memory cell MC of the above embodiment and modification, the magnetoresistance effect element MTJ is provided below the switching element SSL; however, the magnetoresistance effect element MTJ may be provided above the switching element SEL.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit.

What is claimed is:

1. A magnetic memory device comprising:
a magnetoresistance effect element, the magnetoresistance effect element including:
a first ferromagnetic layer;
a second ferromagnetic layer;
a third ferromagnetic layer;
a first non-magnetic layer between the first ferromagnetic layer and the second ferromagnetic layer; and
a second non-magnetic layer between the second ferromagnetic layer and the third ferromagnetic layer, wherein
the second ferromagnetic layer is between the first ferromagnetic layer and the third ferromagnetic layer,
the first non-magnetic layer contains magnesium (Mg) and oxygen (O), and
the third ferromagnetic layer contains silicon (Si) or germanium (Ge).

2. The magnetic memory device according to claim 1, wherein the first ferromagnetic layer and the second ferromagnetic layer contain iron (Fe).

3. The magnetic memory device according to claim 2, wherein:
a magnetization direction of the first ferromagnetic layer is variable; and
a magnetization direction of the second ferromagnetic layer is fixed.

4. The magnetic memory device according to claim 2, wherein:
the first ferromagnetic layer is a storage layer; and
the second ferromagnetic layer is a reference layer.

5. The magnetic memory device according to claim 1, wherein
the magnetoresistance effect element further includes a third non-magnetic layer containing silicon (Si) or germanium (Ge), and
the third ferromagnetic layer is between the second non-magnetic layer and the third non-magnetic layer.

6. The magnetic memory device according to claim 5, wherein the third ferromagnetic layer includes:
a first layer in contact with the second non-magnetic layer, the first layer containing cobalt (Co); and
a second layer in contact with the third non-magnetic layer, the second layer containing platinum (Pt).

7. The magnetic memory device according to claim 5, wherein the third non-magnetic layer further contains boron (B).

8. The magnetic memory device according to claim 7, wherein the third nonmagnetic layer is provided at a side of the third ferromagnetic layer opposite to a side of the third ferromagnetic layer at which the first non-magnetic layer is provided.

9. The magnetic memory device according to claim 8, wherein
the magnetoresistance effect element further includes a fourth non-magnetic layer containing tantalum (Ta) or molybdenum (Mo), and
the fourth non-magnetic layer is provided at a side of the third non-magnetic layer opposite to a side of the third non-magnetic layer at which the first non-magnetic layer is provided.

10. The magnetic memory device according to claim 9, wherein
the magnetoresistance effect element further includes a fifth non-magnetic layer containing hafnium (Hf) or hafnium boride (HfB), and
the fifth non-magnetic layer is provided at a side of the third non-magnetic layer opposite to a side of the third non-magnetic layer at which the first non-magnetic layer is provided.

11. The magnetic memory device according to claim 1, wherein the second non-magnetic layer contains at least one element selected from ruthenium (Ru), osmium (Os), rhodium (Rh), iridium (Ir), vanadium (V), and chromium (Cr).

12. The magnetic memory device according to claim 11, wherein the second ferromagnetic layer and the third ferromagnetic layer have opposite magnetization directions.

13. The magnetic memory device according to claim 2, wherein the second ferromagnetic layer includes:
a first layer in contact with the first non-magnetic layer, the first layer containing iron (Fe); and
a second layer in contact with the second non-magnetic layer, the second layer containing cobalt (Co).

14. The magnetic memory device according to claim 1, wherein a resistance value of the magnetoresistance effect element becomes a first resistance value by a first current which flows from the first ferromagnetic layer to the second ferromagnetic layer, and becomes a second resistance value by a second current which flows from the second ferromagnetic layer to the first ferromagnetic layer.

15. The magnetic memory device according to claim 14, wherein the first resistance value is smaller than the second resistance value.

16. The magnetic memory device according to claim 1, wherein the magnetic memory device, comprises a memory cell including:
the magnetoresistance effect element; and
a switching element coupled in series to the magnetoresistance effect element.

17. The magnetic memory device according to claim 16, wherein the switching element is a two-terminal switching element.

18. The magnetic memory device according to claim 16, wherein the switching element is a metal oxide semiconductor (MOS) transistor.

19. The magnetic memory device according to claim 3, wherein a concentration of silicon (Si) or germanium (Ge) in the third non-magnetic layer is higher than a concentration of silicon (Si) or germanium (Ge) in the third ferromagnetic layer and a concentration of silicon (Si) or germanium (Ge) in the fourth non-magnetic layer.
